(19) United States
(12) Patent Application Publication
(10) Pub. No.: US 2010/0302838 A1
(43) Pub. Date: Dec. 2, 2010

(54) Read disturb-free SMT reference cell scheme

(75) Inventors: Pokang Wang, Los Altos, CA (US); Hsu Kai Yang, Pleasanton, CA (US)

Correspondence Address: SAILE ACKERMAN LLC, 28 DAVIS AVENUE, POUGHKEEPSIE, NY, 12603, US

(73) Assignee: MagIC Technologies, Inc.

(21) Appl. No.: 12/454,925

(22) Filed: May 26, 2009

(51) Int. Cl. G11C 11/00; G11C 7/02; H01L 21/00; G11C 11/14

(52) U.S. Cl. 365/158; 365/210.1; 438/3; 365/171; 257/E21.001

(57) ABSTRACT

We describe a reference cell structure for determining data storing cell resistances in an SMT (spin moment transfer) MTJ (magnetic tunneling junction) MRAM array by comparing data cell currents with those of the reference cell. Since the reference cell also utilizes spin moment transfer (SMT) magnetic tunneling junction (MTJ) cells, there would ordinarily be the danger that the act of reading the reference cell could change its magnetization orientations and be a source of error for subsequent comparisons. Therefore the present invention describes a new circuit arrangement for the reference cell that directs read currents through two SMT MTJ cells in opposite directions so that the transfer of spin moments cannot affect the relative magnetization directions of the cells.

### BACKGROUND OF THE INVENTION

1. Field of the Invention

This invention relates generally to a spin moment transfer (SMT) magnetic random access memory (SMT-MRAM) cell formed in a magnetic tunneling junction (MTJ) configuration. In particular, it relates to the use of such a cell as a reference cell in a manner that eliminates disturbance of the cell's resistance state by the act of reading it.

2. Description of the Related Art

The conventional magnetic tunneling junction (MTJ) device is a form of ultra-high magnetoresistive (MR) device in which the relative orientation of the magnetic moments of parallel, vertically separated magnetized layers, controls the flow of spin-polarized electrons tunneling through a very thin dielectric layer (the tunneling barrier layer) formed between those layers.

Referring to FIG. 1 there is shown a highly schematic illustration of a prior art MTJ cell that, for the purposes of the following descriptions, can be either a standard MTJ cell or, as will be discussed below, a spin moment transfer (SMT) cell. Although the physics of the two types of cell operation are quite different, the cell structures have striking similarities.

The cell display three active layers, a fixed layer (110) formed of magnetic material, a tunnel barrier layer (120) formed of dielectric material and a free layer (130) formed of magnetic material. A bottom electrode (150) provides a mechanism for contacting the cell electrically. Arrows (132) represent the magnetic moments of the free and fixed layers. The magnetic moment of the free layer is free to move under the action of external magnetic fields (in the case of the standard MTJ cell) or under the action of electron torques produced by currents passing through the cell in the case of the SMT cell. The magnetization of the fixed layer is held in place by an interaction with a neighboring layer that is not specifically shown here and can be considered as being a part of layer (110). The magnetization of the free layer is relatively free to move, although the horizontal elliptical cross-section of the cell tends to stabilize the magnetization in a direction along the longer elliptical axis, so that a certain minimum field or torque is required to change the magnetization direction.

When injected electrons pass (for example) through the fixed layer they are spin polarized by interaction with the magnetic moment already present in that layer. The majority of the electrons emerge polarized in the direction of the magnetic moment of that layer, the minority being polarized opposite to that direction. The probability of such a polarized electron then tunneling through the intervening tunneling barrier layer into the free layer depends on the availability of quantum states within the free layer that the tunneling electron can occupy. This number, in turn, depends on the magnetization direction of the free layer. The tunneling probability is thereby spin dependent and the magnitude of the resulting current (tunneling probability times number of electrons impinging on the barrier layer) depends upon the relative orientation of the magnetizations of the magnetic layers above and below the barrier layer. The MTJ device can therefore be viewed as a kind of multi-state resistor, since different relative orientations ( e.g. parallel and antiparallel) of the magnetic moments will change the magnitude of a current passing through the device. In a common type of device configuration (“spin filter”), one of the magnetic layers has its magnetic moment fixed in direction (pinned) by exchange coupling to an antiferromagnetic layer, while the other magnetic layer has its magnetic moment free to move (the free layer). The magnetic moment of the free layer is then made to switch its direction from being parallel to that of the pinned layer, whereupon the tunneling current is large, to being antiparallel to the pinned layer, whereupon the tunneling current is small. Thus, the device is effectively a two-state resistor. The switching of the free layer moment direction (writing) is accomplished by external magnetic fields that are the result of currents passing through conducting lines adjacent to the cell.

FIG. 2a is a highly schematic drawing showing an isometric view of a conventional (non-spin moment transfer) MRAM MTJ cell (100) such as that in FIG. 1 formed between orthogonal word (230) and bit (220) lines and in a read mode. In this mode, transistor (210) is “on” which allows a measurable flow of current through the cell (arrow) enabling the resistance of the cell to be measured by means of a fixed voltage across the cell. The cell is shown with the magnetic moments of its two magnetic layers in an antiparallel configuration, indicating a high resistance.

FIG. 2b shows the same configuration as in FIG. 2a, except the cell is now in its write mode. In this mode, the transistor (210) is off and currents in the word (230) and bit (220) lines do not pass through the cell but produce magnetic fields around it. The magnetic field of the bit line is indicated by arrow (250) and the field of the word line (230) is indicated by arrow (260). The action of these fields together will rotate the magnetic moment of the free layer and produce a change in the resistance of the cell, thereby “writing” on the cell. It is important to note that the read and write modes are fundamentally different in that the read mode requires passage of a current through the cell, while the write mode requires only passage of current through word and bit lines that are adjacent to the cell.

For actual MRAM applications, where the relative orientations of the free and fixed magnetic moments must be stable against perturbations, the MTJ element in FIG. 2a is usually formed with shape anisotropy (as shown in FIG. 1 and in this figure), which occurs when the horizontal cross-sectional shape is made elliptical or some similar shape of high aspect ration. When such an elliptical cell is in its quiescent state (not being written upon), the magnetization of the free layer lies along the longer (easy) axis of the cell. Within this easy axis direction, the free layer magnetization can be directed along the magnetization direction of the pinned layer or opposite to it, i.e., either parallel or anti-parallel to the pinned layer magnetization. In the parallel mode, the cell resistance is minimum, in the anti-parallel mode the cell resistance is maximum. Thus, the storage of digital information is provided by the magnetization direction of the free layer. The field required to switch the free layer magnetization from parallel to anti-parallel mode is called the switching field, Hₛ, and its value is a function of the magnetic anisotropy energy of the cell element.

In the conventional (non-spin moment transfer) MRAM application, two orthogonal external fields are used to program the MRAM cell. These fields are provided by the current carrying bit and word lines between which the cell is positioned. To switch the magnetization direction of a selected cell, both fields are required to be “on” at the position of the selected cell as shown in FIG. 2b. The combination of the two fields will be sufficient to overcome the energy of the shape anisotropy that maintains the cell magnetization in its quiescent direction.

An array of MRAM cells of the type shown in FIG. 2a and 2b suffers from the fact that external write fields (250), (260) at the location of a selected cell can be strong enough to produce unwanted changes in magnetizations of neighboring cells. The fact that such an array of crossed word and bit lines can produce unwanted cell switching is a general problem associated with the use of externally generated magnetic fields to switch MRAM cells. Another problem associated with the use of externally generated magnetic fields to produce switching is the problem of scaling, which is to say that as the cells become smaller so must the current carrying lines and this requires the passage of higher currents through lines of greater resistance, increasing the power consumption of the circuit.

For this reason, a new type of magnetic device, called a spin moment transfer (SMT) device has been developed and seems to eliminate some of the problems associated with the excessive power consumption necessitated by external switching fields. The following prior art all describe various applications using SMT devices and their descriptions of the operation of such devices are incorporated herein by reference.

U.S. Pat. No. 7,362,644 (Yang et al) discloses one of a pair of reference bit lines aligned with the fixed magnetic layer and the other opposing the orientation of the fixed magnetic layer.

U.S. Patent Application 2009/0010088 (Chen et al) shows an MTJ element with a free layer and a pinned layer being orthogonal in a stable state and having a middle current.

U.S. Patent Application 2008/0219044 (Yoon et al) teaches coupling a resistive element between the bit cell and the sense amplifier to prevent read disturbance.

U.S. Patent Application 2006/0113619 (Hung et al) teaches magnetic vectors of the pinned and free layers are arranged orthogonally to form a reference magnetic resistance state.

U.S. Patent Application 2006/0023518 (Iwata) shows a first reference bit line connected to an MTJ element at logic level 0 and a second reference bit line connected to an MTJ element at logic level 1.

The SMT device shares some of the operational features of the conventional MTJ cell described above, except that the switching of the free layer magnetic moment is produced by torques exerted by the spin polarized current itself, rather than by externally generated magnetic fields. In this device, when unpolarized conduction electrons pass through the fixed magnetic layer of FIG. 1, whose magnetic moment is oriented in a given direction, they are preferentially polarized by their passage through that layer by a quantum mechanical exchange interaction with the polarized bound electrons in the layer. Such a polarization can also be imposed on conduction electrons that reflect from the surface of the magnetized layer as well as to those that pass through it. When such a stream of polarized conduction electrons subsequently pass through a second magnetic layer whose polarization direction is not fixed in space (such as the free layer), the polarized conduction electrons exert a torque on the bound electrons in the magnetic layers which, if sufficient, can reverse the polarization of the bound electrons and, thereby, reverse the entire magnetic moment of the magnetic layer. The use of a current internal to the cell to cause the magnetic moment reversal requires much smaller currents than those required to produce an external magnetic field from adjacent current carrying lines to produce the moment switching. The use of the SMT device in MRAM configurations is now well known in the prior art as indicated by the cited prior art above.

Referring to FIG. 3 (adapted from Yoon et al., above), there is shown a schematic illustration of an exemplary prior art SMT-MTJ element (300) being contacted from above by a bit line (320) and from below (through bottom electrode (150)) by a transistor (310) electrically connected to a word line (330). The cell is structured identically to that of FIG. 1. Unlike the configuration of FIG. 2a above, the transistor in FIG. 3 is always on, whether the cell is to be read or to be written upon, because both operations require that a current pass through the cell.

Within an operational MRAM array of SMT-MTJ data storing cells, the magnetization states of individual data storing cells are constantly being read by determining their resistance from a voltage or current measurement and inferring from the results of that measurement whether the magnetizations are parallel or antiparallel and, consequently, what logical value is being stored in the cell. In practice the most efficient and statistically trustworthy way of measuring the resistance of a given cell is, for a given voltage across the cell, to compare the current through the cell with that through a reference cell subjected to the same voltage and whose resistance is known to have a certain value. In this regard, see, for example, reference comparison element 472 in FIG. 4A of Yoon et al., cited above as well as the other prior arts cited above. Thus, an individual measurement of the resistance value of a given data cell is accomplished by means of a comparison measurement with a given reference standard. Comparisons are more readily evaluated than are individual measurements. However, in order to activate the reference cell against which the comparison is to be made, a voltage produced current must be passed through that cell as well. Unfortunately, even though the read current through an SMT-MTJ cell is less than the write current, there is still a probability that the read current will produce sufficient torque transfer to change the polarity of the cell free layer. If this occurs (or has already occurred), the comparison is useless, because of the undetected error in the content of the reference cell. Moreover, once such an error has been introduced into the reference cell, all subsequent measurements based on comparison with the reference cell will be in error.

Referring to FIG. 4, there is shown a schematic diagram of a reference cell arrangement used in the prior art. In this scheme, the reference element is a pair of SMT-MTJ cells, denoted (1) and (2), pre-set in their minimum (for cell (2)), Rₘᵢₙ, and maximum (for cell (1)), Rₘₐₓ resistance states. With such a two-cell reference arrangement, when a voltage is impressed across the cells and word line (230) is activated so as to open read transistors (41) and (42), the conventional current (opposite to the electron flow) will be directed from the reference bit line (320) through cells (1) and (2), through the read transistors (41) and (42) and to ground. The current is equally divided and can be used to sense the resistance states of, for example, two SMT MTJ data cells (not shown). The physics of SMT is such that the direction of the current in SMT MTJ cell (2) will maintain the parallel configuration of magnetizations and keep (2) at Rₘᵢₙ, but there is the possibility of changing cell (1) from Rₘₐₓ to Rₘᵢₙ, which would lead the reference cell configuration to fail in its purpose. Note that the electrons flowing through stack (2) (i.e. the layer configurations of the cell) pass first through the fixed layer, whereupon the electrons are preferentially oriented in the fixed layer polarization direction. As these electrons then flow through the free layer, they will tend to maintain the polarization of that layer since the torque they exert is minimal. On the other hand, electrons flowing through stack (1) are also polarized first by the fixed layer, but they then pass through the oppositely polarized free layer, exerting a maximal torque that is capable of reversing that polarization.

Although the prior art cited above teaches various methods to mitigate failure of a reference cell, none of that art discloses a method that is simple and easy to implement and will eliminate or sharply reduce the effect of a read operation on the resistance state of an SMT-MTJ cell.

### SUMMARY OF THE INVENTION

A first object of this invention is to provide a STM-MTJ reference cell circuit configuration for use in an MRAM device that is robust against read-induced resistance changes.

A second object of the present invention is to provide such a reference cell circuit configuration that is simple and easy to implement.

A third object of the present invention is to provide the fabrication structure that will effectively implement the circuitry of the reference cell.

These objects will be met by a reference cell configuration is which two SMT-MTJ cells are connected in parallel, with one cell in its minimum resistance magnetization state Rₘᵢₙ and the other cell in its maximum resistance state, R_{max,} wherein the cells are oriented so that a read operation allows a flow of read-current through the cells in opposite directions (fixed layer to free layer in one cell, free layer to fixed layer in the other cell). With the opposite direction of current flow, neither cell will have a tendency for its magnetization orientations to change.

### BRIEF DESCRIPTION OF THE DRAWINGS

FIG. 1 is an exemplary elliptical prior art MTJ cell.

FIG. 2a is a schematic representation of a prior-art MTJ MRAM device located at the junction of word and bit lines and operating in its read mode.

FIG. 2b is a schematic representation of the prior art MTJ MRAM device of FIG. 1 a now in its write mode.

FIG. 3 is a schematic representation of a prior art SMT MTJ device in its read or write mode.

FIG. 4 is a schematic illustration of a read-sensitive prior art circuit for a two-cell reference cell configuration for use in measuring resistance values of SMT MTJ cells in an MRAM array.

FIG. 5 is a schematic illustration of the circuit of the present invention for a two-cell reference cell configuration that is resistant to changes in magnetization directions resulting from application of a read current.

FIG. 6 is a schematic illustration of a fabrication that will provide an implementation of the circuit of FIG. 5.

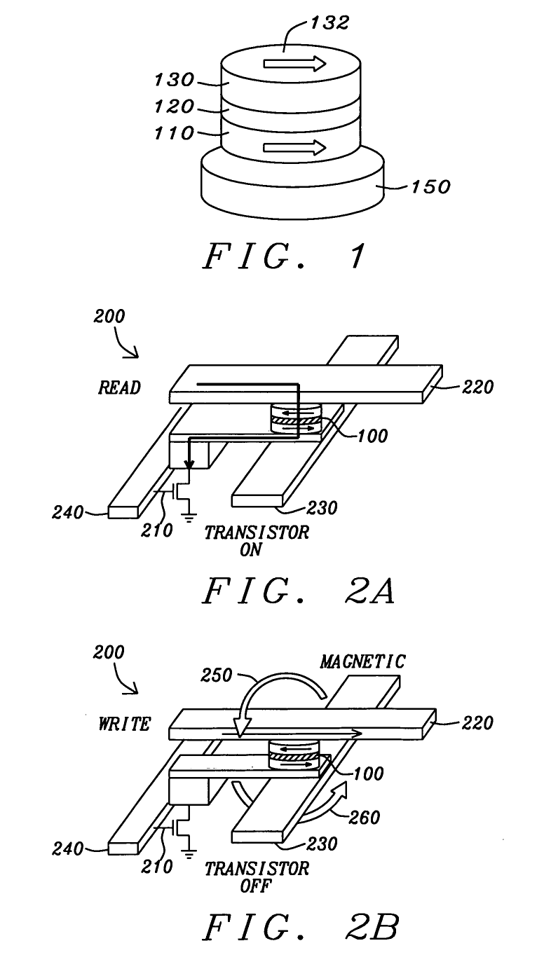

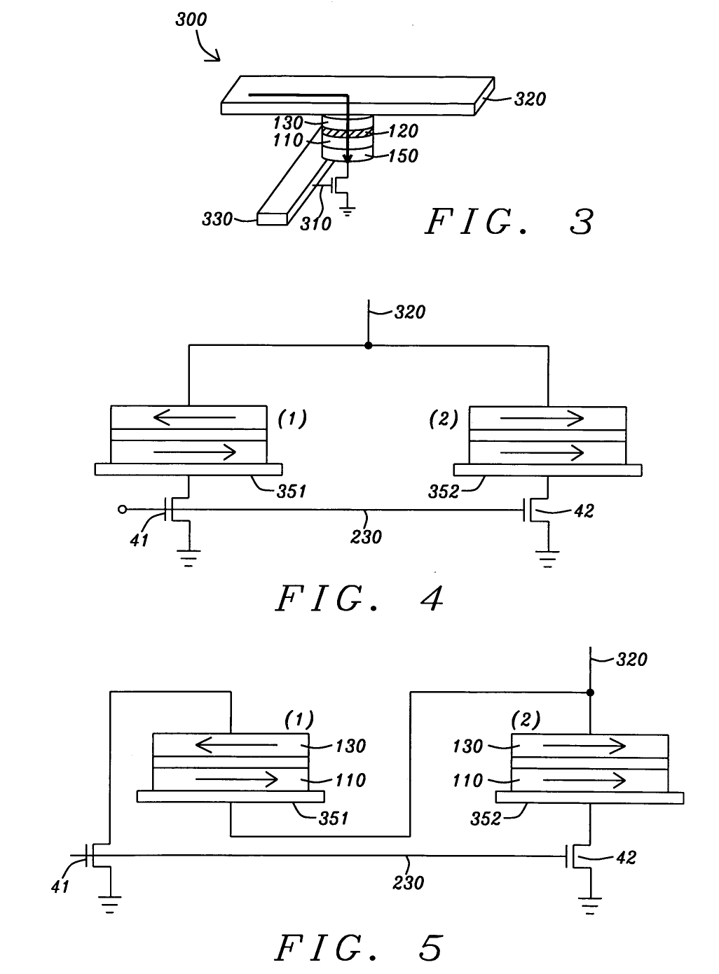

### DESCRIPTION OF THE PREFERRED EMBODIMENTS

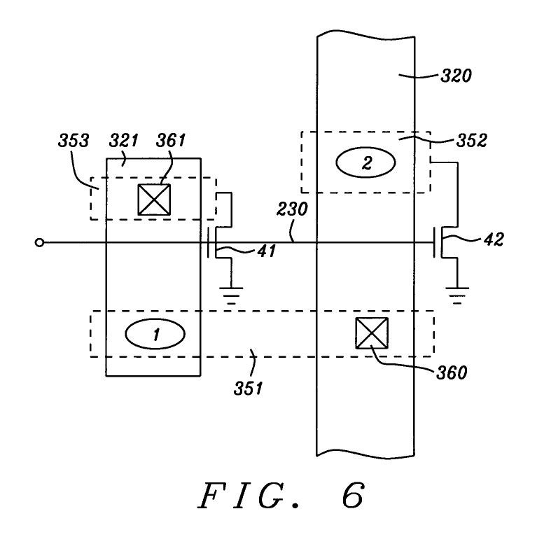

The preferred embodiment of the present invention is a reference cell configuration that is resistant to changes in magnetization direction as a result of read operations. Referring to FIG. 5, there is shown, schematically, the reference cell configuration. It is formed as an interconnection of two STM MTJ cells, with one cell (2) in a parallel magnetization state of minimum resistance, Rₘᵢₙ, and the other cell (1) in an antiparallel magnetization state of maximum resistance, Rₘₐₓ. The reference bit line (320) is connected to the free layer of cell (2) but to the fixed layer of cell (1) at (351). When a voltage to word line (230) opens read transistors (41) and (42), electrons flow through cell (2) from the fixed layer towards the free layer, but they flow through cell (1) from the free layer towards the fixed layer. As a result, the electrons flowing through cell (2) are polarized along the direction of the fixed layer, but they exert very little torque on the magnetization of the free layer because its magnetization is already along the same direction as the spins of the electrons. Hence, cell (2) has virtually no tendency to change its magnetization directions. In the case of cell (1), however, the electrons first pass through the free layer, where they are preferentially polarized in that direction. When they subsequently pass through the fixed layer, although they can exert a torque on the fixed layer magnetization, the magnetization is fixed and has no tendency to change direction. Thus, neither cell will change its magnetization direction and each cell will retain its original resistance value. As a result, repetitive activation of the cell combination will not produce resistance changes in the two cells and the total current flow will be an effective reference standard for comparison with storage cells in an MRAM array.

Referring next to FIG. 6, there is shown a schematic drawing of a material layout to implement the circuit of FIG. 5. Using methods well known in the prior art, the implementation will preferably be fabricated in the following sequence of steps.

First, two transistors, (41), (42) and a common read word line (230) connecting their gate electrodes are formed on the substrate. The drain of each transistor is connected to ground. Then bottom electrodes (351), (352) and an adjacent bottom electrode metal piece (353) are formed.

Two SMT MTJ stacks are then formed on the bottom electrodes, then elliptically patterned to form the SMT MTJ cells (1) and (2), now respectively on bottom electrodes (351) and (352). The MTJ stacks (and the final patterned cells) conform basically to the schematic three layered structure (free layer, barrier layer, fixed layer) as illustrated in FIG. 1.

The two MTJ cells (1), (2), their bottom electrodes (351) and (352), the word line (230), the bottom electrode metal piece (353) and the transistors (41) and (42) are then blanketed with a dielectric layer (not specifically illustrated) for insulating purposes. The dielectric layer is then planarized and conducting vias (360) and (361) are formed through the dielectric layer to electrically contact the bottom electrode (351) of cell (1) and the bottom electrode metal piece (353). Upper surfaces of cells (1) and (2) are substantially exposed by the planarization for subsequent electrical contacts to be made.

Next, a bit line metal layer (320) and an adjacent bit line metal piece (321) are formed over the planarized surface of the insulating layer. Bit line metal layer (320) electrically contacts the top surface of the MTJ cell (2) and also electrically contacts the conducting via (360). At the same time, bit line metal piece (321) contacts the top surface of MTJ cell (1) and also electrically contacts the conducting via (361).

A source of transistor (42) is electrically connected to the bottom electrode (352) of cell (2). A source of transistor (41) is electrically connected to bottom electrode metal piece (353).

When read transistors (41) and (42) are simultaneously on as a result of activating the word line (230), conventional current flows from bit line (320) “down” through cell (2) (from free layer towards fixed layer) and “up” (from fixed layer towards free layer) through cell (1), maintaining the pre-set polarities of both cell free layers for the reasons set forth above.

As shown in FIG. 5, the two MTJ cells (1) and (2) are finally magnetized as shown, with cell (1) being set in a maximum resistance state of antiparallel magnetizations and cell (2) being set in its minimum resistance state, with parallel magnetizations. Upon activation of the word line (230), currents will flow through each of the MTJ cells without disturbing their resistances, so that the total current is an effective reference measure for the storage MTJ cells in an MRAM array.

As is finally understood by a person skilled in the art, the preferred embodiments of the present invention are illustrative of the present invention rather than limiting of the present invention. Revisions and modifications may be made to methods, materials, structures and dimensions employed in forming and providing a read disturb-free reference cell using two interconnected spin transfer SMT MTJ cells, while still forming and providing such a device and its method of formation in accord with the spirit and scope of the present invention as defined by the appended claims.

What is claimed is:

1. A reference cell for an MRAM array, comprising:
a first SMT MTJ cell including a fixed layer and a free layer set in a maximum resistance magnetization configuration;
a second SMT MTJ cell including a fixed layer and a free layer set in a minimum resistance magnetization configuration;
a word line for accessing each of said first and second cells through an accessing transistor;
a bit line for sending a reference current through each of said first and second cells when said word line is accessed and said transistors are on; wherein
a first portion of said reference current flows through said first cell in a direction from a fixed to a free layer and a remaining portion of said reference current flows in said second cell in a direction from a free layer to a fixed layer, whereby
said magnetization configurations are resistant to change caused by said reference current.

2. The reference cell of claim 1 wherein each of said SMT MTJ cells is patterned with a horizontal cross-sectional shape of high aspect ratio to provide a magnetic anisotropy.

3. The reference cell of claim 2 wherein said cross-sectional shape is elliptical.

4. The reference cell of claim 1 wherein magnetizations of said free layer and said fixed layer of said first SMT MTJ cell are in an anti-parallel configuration and wherein magnetizations of said free layer and said fixed layer of said second SMT MTJ cell are in a parallel configuration.

5. The reference cell of claim 4 wherein said second SMT MTJ cell retains its magnetization configuration because said second portion of said reference current exerts no torque on the magnetic moment of said free layer and wherein said first SMT MTJ cell retains its magnetization configuration because a torque produced by said remaining portion of said current is insufficient to change the magnetization of a fixed layer.

6. The reference cell of claim 1 wherein each of said SMT MTJ cells retains its resistance value subsequent to passage of said reference current.

7. The reference cell of claim 1 wherein said first quantity of current and said second quantity of current are averaged and divided into two equal currents for use as reference currents in determining the resistances of data storing SMT MTJ cells.

8. The reference cell of claim 7 wherein said bit line maintains the same voltage across said first and second cells with respect to a ground whenever said reference cell is used for resistance determinations of data storing SMT MTJ cells.

9. The reference cell of claim 8 wherein said reference currents do not change as a result of successive uses of said reference cell, whereby said current is a reliable standard for comparison purposes.

10. The reference cell of claim 9 wherein resistance states of data storing SMT MTJ cells are determined by comparing currents through said data storing SMT MTJ cells with said reference current when equal voltages are applied across said reference cell and said data storing SMT MTJ cells.

11. A method of fabricating a reference cell for an MRAM array comprising:
providing a substrate;
forming on said substrate two substantially identical read transistors, wherein gate electrodes of said read transistors are connected to a common word line and wherein drain connections of said transistors are connected to ground;
forming a separate bottom electrode layer on said substrate for each of two SMT MTJ cells;
forming a separate bottom electrode metal piece adjacent to one of said electrode layers;
forming a first SMT MTJ cell on one of said bottom electrode layers and a second SMT MTJ cell on the other of said bottom electrode layers, wherein the first SMT MTJ cell is proximal to said bottom electrode metal piece;
forming a blanket dielectric layer surrounding said first and second MTJ cells, said bottom electrode metal piece, said two read transistors and said common word line;
planarizing said dielectric layer, thereby substantially exposing upper surfaces of said two SMT MTJ cells;
forming through said planarized dielectric layer a first and second conducting via, wherein said first conducting via electrically contacts the bottom electrode of said first SMT MTJ cell and said second conducting via electrically contacts said bottom electrode metal piece;
forming a bit line layer and an adjacent bit line metal piece on said planarized dielectric layer, said bit line layer electrically contacting said first via and electrically contacting an upper surface of said second SMT MTJ cell and said bit line metal piece electrically contacting said second via and an upper surface of said first SMT MTJ cell;
connecting a source of one of said two transistors to a lower electrode of said second SMT MTJ cell;
connecting a source of the second of said two transistors to said bottom electrode metal piece.

12. The method of claim 11 further comprising:
magnetizing said first SMT MTJ cell to form an anti-parallel magnetization of a free layer and a fixed layer;
magnetizing said second SMT MTJ cell to form a parallel magnetization of a free layer and a fixed layer.

13. The method of claim 11 wherein each of said two SMT MTJ cells is patterned in a horizontal cross-sectional shape of high aspect ratio to provide a shape-induced magnetic anisotropy.

14. The method of claim 13 wherein said shape is elliptical.

15. An MRAM array, comprising:
a regular two dimensional orthogonal array of data storing STM MTJ cells;
reference cells for measuring resistance states of said storage STM MTJ cells; wherein
the resistances of said reference cells are unaffected by repetitive use.

16. The MRAM array of claim 15 wherein said reference cells comprise a parallel connection of two STM MTJ cells, wherein a first one of said STM MTJ cells is magnetized in a configuration corresponding to a maximum resistance state and a second one of said cells is magnetized in a configuration corresponding to a minimum resistance state and wherein, a reference current, divided so as to flow through each of said cells, flows through each said cell in such a direction that the relative directions of magnetizations in said cell layers does not change.

17. The MRAM array of claim 16 wherein each of said SMT MTJ cells in said reference cell is patterned with a horizontal cross-sectional shape of high aspect ratio to provide a magnetic anisotropy.

18. The MRAM array of claim 16 wherein said cross-sectional shape is elliptical.

19. The MRAM array of claim 15 wherein one reference cell is provided as a reference for a pair of STM MTJ data storage cells.

20. MRAM array of claim 16 wherein said reference current is a sum of currents passing through each of said SMT MTJ cells and said currents are averaged and divided into two equal currents for use as reference currents in determining the resistances of said data storing SMT MTJ cells.
